(19) United States
(12) Patent Application Publication
(10) Pub. No.: US 2015/0155434 A1
(43) Pub. Date: Jun. 4, 2015

(54) LIGHT EMITTING DIODE AND MANUFACTURING METHOD THEREOF

(71) Applicant: Electronics and Telecommunications Research Institute, Daejeon (KR)

(72) Inventors: Sung Bock KIM, Daejeon (KR); Sung Bum BAE, Daejeon (KR)

(73) Assignee: Electronics and Telecommunications Research Institute, Daejeon (KR)

(21) Appl. No.: 14/192,299

(22) Filed: Feb. 27, 2014

(30) Foreign Application Priority Data
Dec. 3, 2013 (KR) 10-2013-0149294

(51) Int. Cl. H01L 33/10; H01L 33/32

(52) U.S. Cl. CPC H01L 33/10; H01L 33/32

(57) ABSTRACT

Disclosed are a light emitting diode including: a buffer layer formed on a substrate; a Distributed Bragg Reflector (DBR) formed in a multilayer structure, in which mask patterns including opening regions and semiconductor layers formed on the mask patterns while being filled in the opening regions of the mask patterns are alternately formed, and formed on the buffer layer; and a light emitting structure formed on the DBR, and a manufacturing method thereof.

### CROSS-REFERENCE TO RELATED APPLICATION

This application is based on and claims priority from Korean Patent Application No. 10-2013-0149294, filed on Dec. 3, 2013, with the Korean Intellectual Property Office, the disclosure of which is incorporated herein in its entirety by reference.

### BACKGROUND

1. Field

The present invention relates to a light emitting diode and a manufacturing method thereof, and more particularly, to a high power light emitting diode, and a manufacturing method thereof.

2. Discussion of Related Art

A Light Emitting Diode (LED) is a device for converting an electrical signal to light by using a characteristic of a compound semiconductor. More particularly, in the LED, holes provided from a p-type semiconductor layer are recombined with electrons provided from an n-type semiconductor layer in an active layer to generate light. The LED has advantages of low power consumption, semi-permanent lifetime, a rapid response speed, stability, and an environment friendly property, compared to a light source, such as a florescent light and an incandescent light, thereby being used in various field as a light source. Particularly, a nitride based LED having a wide band gap has an advantage of emitting light of green, blue, and a near ultraviolet ray band, so that an application field thereof becomes considerably expanded.

Performance of the aforementioned nitride-based LED is determined according to internal quantum efficiency and light extraction efficiency. The efficiency of the nitride-based LED is generally determined based on internal quantum efficiency according to the amount of photons generated by electrons injected into the active layer, and light extraction efficiency according to the amount of extracted photons from generated photons in the active layer of the LED.

A method of improving internal quantum efficiency includes a method of reducing a threading dislocation density and a method of decreasing a piezoelectric field. Particularly, it is very significant to improve internal quantum efficiency by forming an active layer having a small lattice mismatch by reducing a threading dislocation density.

As a method of improving internal quantum efficiency by reducing a piezoelectric field, research on a method of improving overlapping between a wave function of an electron and a wave function of a hole by using a semi-polar substrate or a non-polar substrate is conducted. However, the research has not been utilized in actual manufacturing of the LED.

As a method of reducing a threading dislocation density, a method of improving a quality of an active layer by growing an epi layer on a Patterned Sapphire Substrate (PPS) so that dislocation generated by a lattice mismatch between the substrate and the epi layer is prevented from being progressed to an upper side has been widely used.

The method of improving photons radiated to the outside of the LED includes a method of preventing reduction of light extraction by total reflection by adjusting an angle of reflection of light generated by using a PSS substrate in a lateral chip, and a method of improving efficiency of light extraction by increasing an escape angle of light by using a surface texturing method of processing a surface to be rough in a flip chip or a vertical chip.

As described above, the PSS substrate may improve internal quantum efficiency and increase photons radiated to the outside, the PSS substrate is mainly used for manufacturing the LED of high efficiency. The nitride-based LED using the PSS substrate is based on a technology of growing the GaN buffer layer at a low temperature. However, the GaN buffer layer cannot be used in the LED (for example, the UV-LED) having larger energy of than a band gap energy of GaN. The reason is that when the GaN buffer layer is used in the UV-LED, the GaN absorbs light, so that light is not nearly radiated to the outside.

Accordingly, other material, except for GaN, needs to be introduced as the UV-LED buffer layer, but a technology of growing another material other than GaN on the PSS substrate has not been established well. Accordingly, the PSS substrate is not used in manufacturing the UV-LED. As a result, in order to improve efficiency of light extraction of the UV-LED, it is necessary to dramatically reduce a dislocation density by 100 times or more from 10¹⁰/cm² to 10⁸/cm² to improve internal quantum efficiency.

### SUMMARY

The present invention has been made in an effort to provide a light emitting diode capable of improving light extraction efficiency by reducing a dislocation density and improving reflectance.

An embodiment of the present invention provides a light emitting diode, including: a buffer layer formed on a substrate; a Distributed Bragg Reflector (DBR) formed in a multilayer structure, in which mask patterns including opening regions and semiconductor layers formed on the mask patterns while being filled in the opening regions of the mask patterns are alternately formed, and formed on the buffer layer; and a light emitting structure formed on the DBR.

Another embodiment of the present invention provides a method of manufacturing a light emitting diode, including: forming a buffer layer on a substrate; forming a Distributed Bragg Reflector (DBR) having a multilayer structure by alternately stacking mask patterns and semiconductor layers on the buffer layer; and forming a light emitting structure on the DBR.

According to the embodiment of the present invention, a Distributed Bragg Reflector (DBR) is formed by alternately stacking mask patterns preventing threading dislocation and semiconductor layers covering the mask patterns in a multilayer form, and the DBR is used as the light extraction structure. Accordingly, the present invention may prevent the threading dislocation from being progressed to the light emitting structure through the mask pattern to provide the high quality active layer having a low dislocation density, thereby improving internal quantum efficiency. Simultaneously, the present invention may reflect light radiated from the light emitting structure to head toward the substrate side to the outside (particularly, the upper side of the light emitting structure), thereby improving light extraction efficiency.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIG. 1 is a cross-sectional view illustrating a light extraction structure according to an exemplary embodiment of the present invention;

FIG. 2 is a graph illustrating a refractive index according to a wavelength of a mask of SiO₂ according to the exemplary embodiment of the present invention;

FIG. 3 is a graph illustrating a refractive index according to a wavelength of a semiconductor layer of AlN according to the exemplary embodiment of the present invention;

FIG. 4 is a graph illustrating reflectance according to a wavelength according to the number of stacked pairs of the mask pattern and the semiconductor layer forming the light extraction structure according to the exemplary embodiment of the present invention;

FIG. 5 is a perspective view illustrating the light emitting diode according to the exemplary embodiment of the present invention;

FIGS. 6A to 6F are perspective views for describing a manufacturing method of the light emitting diode illustrated in FIG. 5; and

FIG. 7 is a perspective view illustrating a part of the light emitting diode according to the exemplary embodiment of the present invention.

### DETAILED DESCRIPTION

Hereinafter, an embodiment of the present invention will be described with reference to the accompanying drawings in detail. However, the present invention is not limited to an embodiment disclosed below and may be implemented in various forms and the scope of the present invention is not limited to the following embodiments. Rather, the embodiment is provided to more sincerely and fully disclose the present invention and to completely transfer the spirit of the present invention to those skilled in the art to which the present invention pertains, and the scope of the present invention should be understood by the claims of the present invention.

FIG. 1 is a cross-sectional view illustrating a light extraction structure according to an exemplary embodiment of the present invention.

Referring to FIG. 1, the light extraction structure according to the exemplary embodiment of the present invention includes a Distributed Bragg Reflector (DBR) including mask patterns 10 and semiconductor layers 20 alternately stacked, and formed in a multilayer structure. The number of pairs 30 of the mask patterns 10 and the semiconductor layers 20 are N (N is a natural number equal to or larger than 2) to form the DBR.

The mask pattern 10 includes an opening region. That is, the mask pattern 10 is formed to partially block a surface of a lower layer. The mask pattern 10 may block threading dislocation and is formed of a material which does not absorb light. For example, the mask pattern 10 may be formed of a dielectric material having a transmittance characteristic, and more particularly, the mask pattern 10 may be formed of a dielectric material, such as SiO₂ and SiNₓ (x is a positive number).

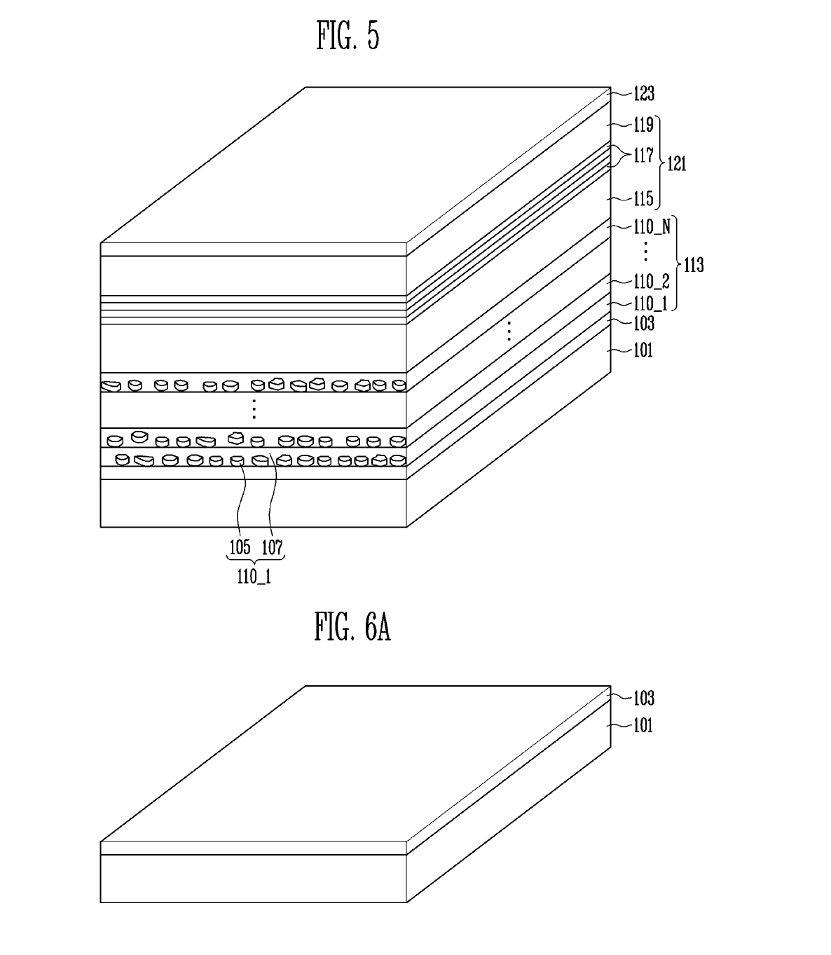

The semiconductor layer 20 includes a first region 20a filled in the opening region of the mask pattern 10, and a second region 20b extended from the first region 20a to cover the first region 20a and the mask pattern 10. The semiconductor layer 20 serves to improve a quality of a light emitting structure by decreasing a dislocation density of a material layer forming the light emitting structure to be described below with reference to FIG. 5, and may be formed of a nitride-based semiconductor. For example, in a case where the light emitting structure has a wavelength of a visual light region, the semiconductor layer 20 may be formed of GaN, but in a case where the light emitting structure is an UVC-LED having a wavelength of 280 nm, the semiconductor layer 20 may be formed of a nitride-based semiconductor, such as AlN or AlGaN. Particularly, the semiconductor layer 20 is an epi layer grown from a buffer layer to be described below with reference to FIG. 5.

Hereinafter, a layer in which the mask pattern 10 and the first region 20a of the semiconductor layer 20 filled in the opening region of the mask pattern 10 are formed is defined as a first layer A, and a layer formed of the second region 20b of the semiconductor layer 20 is defined as a second layer B.

As described above, in the exemplary embodiment of the present invention, a light extraction structure formed of the DBR is formed by repeatedly stacking the pair of the mask pattern 10 and the semiconductor layer 20. Accordingly, dislocation by the lattice mismatch is block by the mask pattern 10, so that the dislocation density is decreased as being close to an upper layer of the DBR. Accordingly, the light extraction structure according to the exemplary embodiment of the present invention may improve internal quantum efficiency of the active layer in the light emitting structure to be descried below with reference to FIG. 5.

Further, the light extraction structure according to the exemplary embodiment of the present invention forms the DBR formed by repeatedly stacking the pair of the mask pattern 10 and the semiconductor layer 20, so that it is possible to reflect light, which is emitted from the light emitting structure to be descried below with reference to FIG. 5 to move toward the substrate side, to the outside, thereby improving light extraction efficiency.

In order to obtain high reflectance through the DBR according to the exemplary embodiment of the present invention, a thickness d₁ of the first layer A is set to meet Equation 1 below.

$${d}_{1} = \frac{λ}{4 \times {n}_{eff}} , \qquad [ Equation 1 ]$$

In Equation 1, the thickness d₁ is a thickness of the mask pattern 10 or a thickness of the first region 20a of the semiconductor layer 20. λ indicates a wavelength of light emitted in the light emitting structure desired to be formed, and n_{eff} indicates an effective refractive index of the first layer A.

The effective refractive index of the first layer A is defined as Equation 2 below.

n_{eff}=(1−α)n₂+αn₁ [Equation 2],

In Equation 2, α indicates surface coverage of the mask pattern 10, which is a ratio of a deposition area of the mask pattern 10 deposited on a surface of the lower layer, n₁ indicates a refractive index of the mask pattern 10, and n₂ indicates a refractive index of the semiconductor layer 20.

Further, In order to obtain high reflectance through the DBR according to the exemplary embodiment of the present invention, a thickness d₂ of the second layer B is set to meet Equation 3 below.

$${d}_{2} = \frac{λ}{4 \times {n}_{2}} , \qquad [ Equation 3 ]$$

In Equation 3, the thickness d₂ is a thickness of the second region 20b of the semiconductor layer 20. λ indicates a wavelength of light emitted in the light emitting structure desired to be formed, and n₂ indicates a refractive index of the semiconductor layer 20.

As described above, in order to obtain optimized reflectance through the DBR light extraction structure of the present invention, the thicknesses of the first layer A and the second layer B need to be set considering the effective refractive index of the first layer A, the surface coverage of the mask pattern 10, the refractive index of the mask pattern 10, the refractive index of the semiconductor layer 20, and the wavelength of the light emitting structure.

For example, in a case where the mask pattern 10 of the DBR light extraction structure applied to the UVC-LED having the wavelength of 280 nm is formed of SiO₂ having the surface coverage of 50%, and the semiconductor layer 20 is formed of AlN, the thickness of the first layer A is 35.9 nm according to aforementioned Equations 1 and 2, and the thickness of the second layer B is 30.0 nm according to aforementioned Equation 3.

Reflectance R in the light extraction structure according to the exemplary embodiment of the present invention is defined as Equation 4 below.

$$R = {[ \frac{{{n}_{0} ( {n}_{2} )}^{2 N} - {{n}_{s} ( {n}_{eff} )}^{2 N}}{{{n}_{0} ( {n}_{2} )}^{2 N} - {{n}_{s} ( {n}_{eff} )}^{2 N}} ]}^{2} , \qquad [ Equation 4 ]$$

In Equation 4, n₀ indicates a refractive index of the semiconductor layer (for example, reference numeral 115 of FIG. 5) which is in contact with ah upper portion of the DBR light extraction structure, n_{eff} indicates the effective refractive index of the first layer A obtained through Equation 2, n₂ indicates a refractive index of the semiconductor layer 20, nₛ indicates a refractive index of the substrate, and N indicates the number of stacked pairs 30 of the mask pattern 10 and the semiconductor layer 20.

The reflectance of the DBR light extraction structure according to the exemplary embodiment of the present invention may be set to a desired value according to the material of the mask pattern 10, the material of the semiconductor layer 20, and the surface coverage of the mask pattern 10 by using Equation 4.

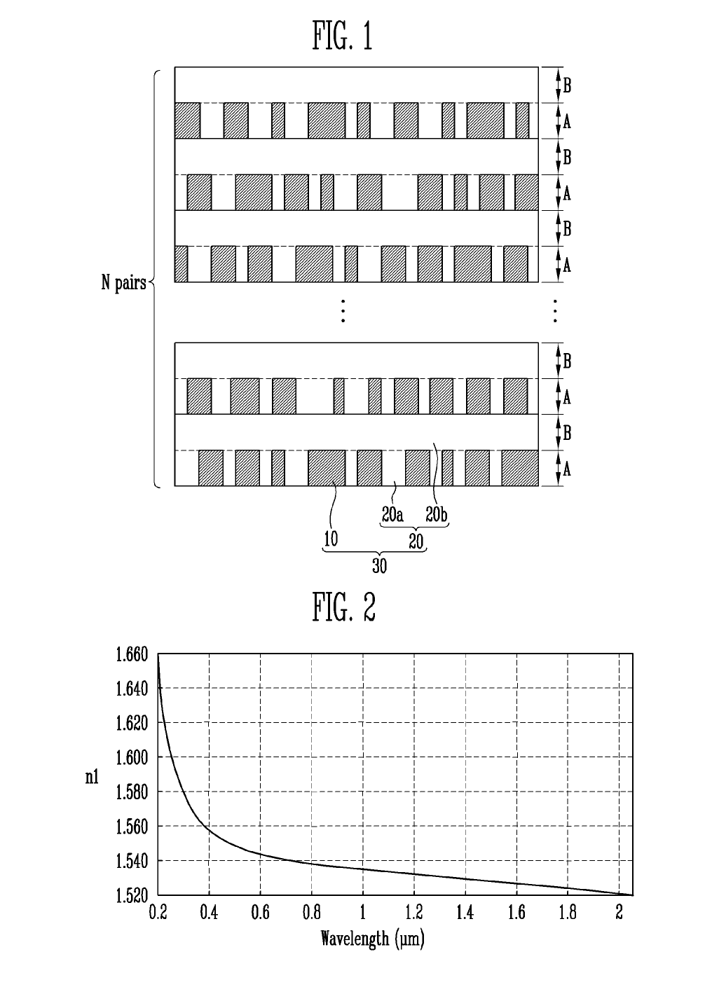

Hereinafter, the reflectance of the DBR light extraction structure according to the exemplary embodiment of the present invention will be described in more detail with reference to FIGS. 2 to 4. Hereinafter, a case of adopting the DBR light extraction structure in which the mask pattern 10 formed of SiO₂ having the surface coverage of 50% and the semiconductor layer 20 formed of AlN are alternately and repeatedly stacked on a rear surface of the UVC-LED having a wavelength of 280 nm (=0.28 μm) will be described as an example, but the present invention is not limited thereto.

FIG. 2 is a graph illustrating a refractive index according to a wavelength of the mask pattern according to the exemplary embodiment of the present invention. Especially, FIG. 2 is a graph illustrating a refractive index according to a wavelength of the mask pattern formed of SiO₂.

The refractive index n₁ of the mask pattern formed of SiO₂ illustrated in FIG. 2 meets Equation 5 below.

$${n}_{1}^{2} = 1.286 + \frac{1.0704 {λ}^{2}}{{λ}^{2} - 1.00586 \times {10}^{- 2}} + \frac{1.1020 {λ}^{2}}{{λ}^{2} - {10}^{2}} \\ ( λ = wavelength ( μm ) ) , \qquad [ Equation 5 ]$$

According to Equation 5, the refractive index of the mask pattern formed of SiO₂ in the wavelength of 280 nm is 1.5853.

FIG. 3 is a graph illustrating a refractive index according to a wavelength of the semiconductor layer according to the exemplary embodiment of the present invention. Especially, FIG. 3 is a graph illustrating a refractive index according to a wavelength of the semiconductor layer formed of AlN.

The refractive index n₂ of the semiconductor layer formed of AlN illustrated in FIG. 3 meets Equation 6 below.

$${n}_{2}^{2} = 3.1399 + \frac{1.3786 {λ}^{2}}{{λ}^{2} - {0.1715}^{2}} + \frac{3.861 {λ}^{2}}{{λ}^{2} - {15.03}^{2}} \\ ( λ = wavelength ( μ m ) ) , \qquad [ Equation 6 ]$$

According to Equation 6, the refractive index of the semiconductor layer formed of AlN is 2.3119.

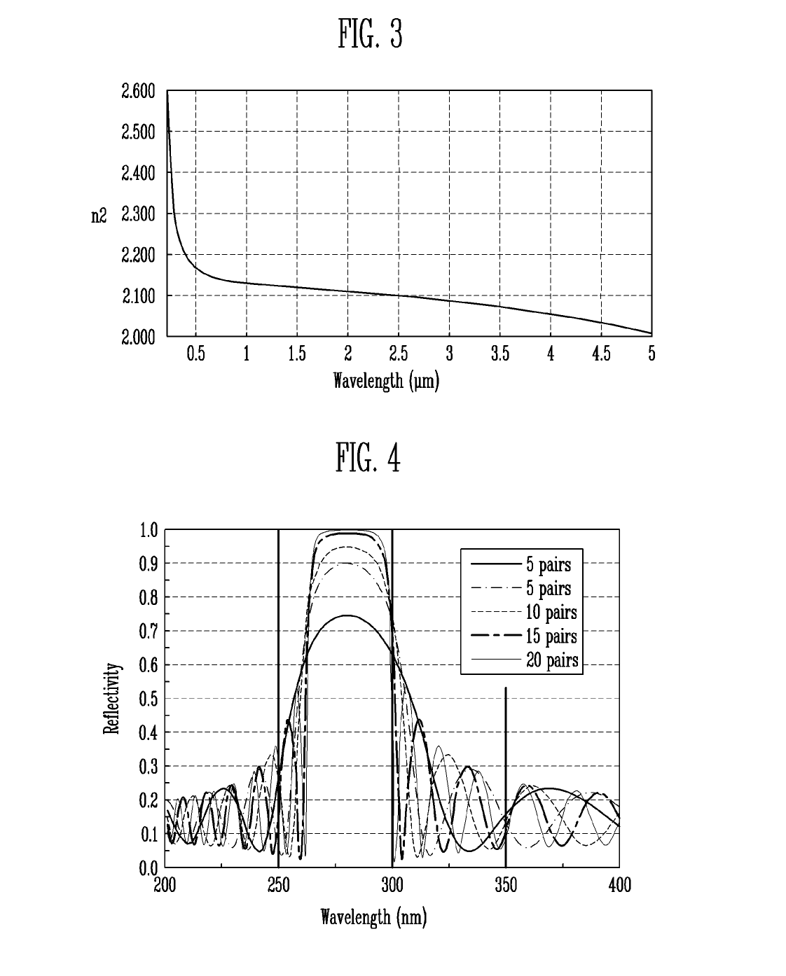

FIG. 4 is a graph illustrating reflectance according to a wavelength according to the number of stacked pairs of the mask pattern and the semiconductor layer forming the light extraction structure according to the exemplary embodiment of the present invention. Especially, FIG. 4 is a graph illustrating reflectance of the DBR light extraction structure formed by setting the wavelength of the light emitting structure is set to 280 nm, setting the surface coverage of the mask pattern formed of SiO₂ to 50%, and alternately and repeatedly stacking the mask pattern formed of SiO₂ and the semiconductor layer formed of AlN.

When it is assumed that the surface coverage of the mask pattern formed of SiO₂ is 50% of the surface area, the effective refractive index n_{eff} of the first layer A of FIG. 1 is 1.9486 according to Equation 2.

The reflectance according to the wavelength will be calculated by using Equation 1. As illustrated in FIG. 4, it is possible to different reflectance according to the number of stacked pairs of the mask pattern and the semiconductor layer. More particularly, as illustrated in FIG. 4, when 5 pairs of mask patterns formed of SiO₂ and semiconductor layers of AlN are stacked, about reflectance of 75% may be obtained, but when 8 pairs or more of mask patterns formed of SiO₂ and semiconductor layers of AlN are stacked, reflectance of 90% or more may be obtained, and when 15 pairs or more of mask patterns formed of SiO₂ and semiconductor layers of AlN are stacked, reflectance of 99% or more may be obtained. Accordingly, it is possible to form the DBR light extraction structure having reflectance of 99% or more by stacking 15 pairs or more of mask patterns formed of SiO₂ and semiconductor layers of AlN. In addition, it is possible to the DBR light extraction structure having various numbers of stacks and various reflectance according to the surface coverage of the mask pattern, the material of the mask pattern, and the material of the semiconductor layer.

As described above, the reflectance of the DBR light extraction structure according to the exemplary embodiment of the present invention may be optimized by controlling the number of stacked pairs of mask patterns and semiconductor layers.

Hereinafter, a light emitting diode employing the light extraction structure according to the exemplary embodiment of the present invention and a manufacturing method thereof will be described with reference to FIGS. 5 to 7.

Referring to FIG. 5, the light emitting diode according to the exemplary embodiment of the present invention includes a buffer layer 103 formed on a substrate 101, a DBR light extraction structure 113 formed on the buffer layer 103, and a light emitting structure 121 formed on the DBR light extraction structure 113.

The substrate 101 may be formed of a semiconductor material or a conductive material, and may be formed of, for example, sapphire.

The buffer layer 103, which is a layer formed to relieve a difference in a lattice constant between the substrate 101 and a semiconductor layer 107, may be a single crystalline layer formed by a growing method. The buffer layer 103 may enable the semiconductor layer 107 to be easily grown, and may improve crystallizability of the semiconductor layer 107 formed on the buffer layer 103. The buffer layer 103 may be formed of a nitride semiconductor. For example, in a case where the light emitting structure 121 has a wavelength of a visual light region, the semiconductor layer 107 may be formed of GaN, but in a case where the light emitting structure 121 is an UVC-LED having a wavelength of 280 nm, the semiconductor layer 107 may be formed of AlN or AlGaN.

The DBR light extraction structure 113 includes pairs 110_1 to 110_N (N is a natural number equal to or larger than 2) of mask patterns 105 and semiconductor layers 107 alternately stacked on the buffer layer 103. The semiconductor layer 107 is formed to be filled in an opening region of the mask pattern 105 and cover the mask pattern 105. The mask pattern 105 may be formed of the structure and the material aforementioned with reference to FIG. 1. The semiconductor layer 107 is formed of the structure and the material aforementioned with reference to FIG. 1. In the DBR light extraction structure 113 according to the exemplary embodiment of the present invention, dislocation density is decreased as being close to an upper layer as described with reference to FIG. 1. In this case, in order to implement optimized reflectance of the DBR light extraction structure 113, a thickness of each of the pairs 110_1 to 110_N of mask patterns 105 and semiconductor layers 107 is determined by aforementioned Equation 1 to 3, and the number of stacked pairs 110_1 to 110_N of mask patterns 105 and semiconductor layers 107 is determined through aforementioned Equation 2 and Equation 4. Accordingly, the DBR light extraction structure 113 according to the exemplary embodiment of the present invention improves internal quantum efficiency by decreasing dislocation density. And the DBR light extraction structure 113 may reflect light heading toward a lower side to an upper side, thereby improving light extraction efficiency.

The light emitting structure 121 includes an n-type semiconductor layer 115 formed on the DBR light extraction structure 113, an active layer 117 formed on the n-type semiconductor layer 115, a p-type semiconductor layer 119 formed on the active layer 117. A semiconductor layer formed of GaN or InGaN, in which an n-type dopant is doped, may be used as the n-type semiconductor layer 115, but in order to form the UVC-LED, a material layer, in which an n-type dopant is doped in a semiconductor layer, such as AlGaN, AlN, and InAlGaN, may be used as the n-type semiconductor layer 115. The n-type semiconductor layer 115 may provide the active layer 117 with electrons. A semiconductor layer formed of GaN or InGaN, in which a p-type dopant is doped, may be used as the p-type semiconductor layer 119, but in order to form the UVC-LED, a material layer, in which a p-type dopant is doped in a semiconductor layer, such as AlGaN, AlN, and InAlGaN, may be used as the p-type semiconductor layer 119. The p-type semiconductor layer 119 may provide the active layer 117 with holes. The electrons from the n-type semiconductor layer 115 and the holes from the p-type semiconductor layer 119 are injected into the active layer 117 and recombined to emit light. The active layer 117 may be formed of a single quantum well structure, a Multiple Quantum Well (MQW) structure, a quantum wire structure, a quantum dot structure, and the like by using a compound semiconductor of a group III and V element.

A p contact layer 123 may be further formed on the p-type semiconductor layer 119.

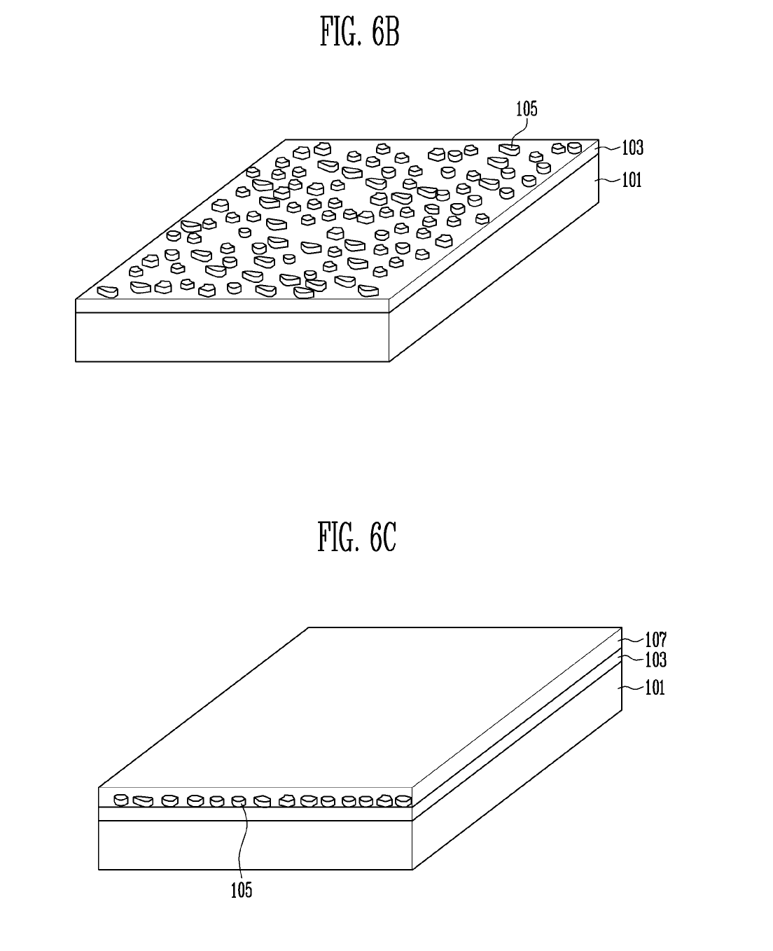

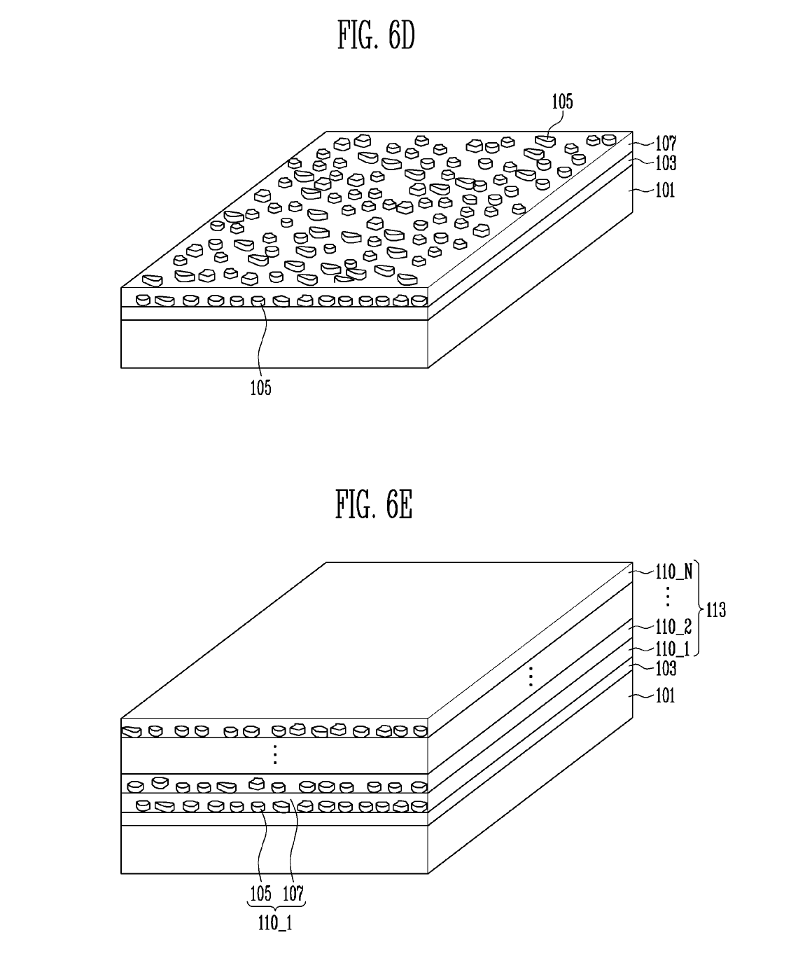

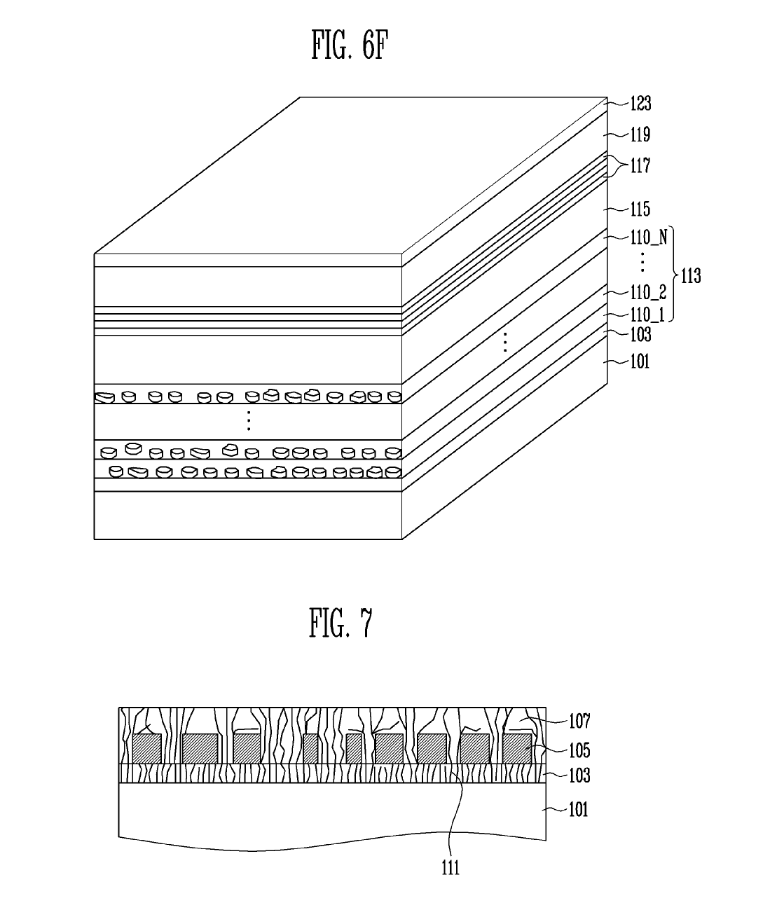

FIGS. 6A to 6F are perspective views for describing a manufacturing method of the light emitting diode illustrated in FIG. 5.

Referring to FIG. 6A, a buffer layer 103 is formed on a substrate 101. The buffer layer 103 may be grown as a single crystalline layer on the substrate 101.

Referring to FIG. 6B, a mask pattern 105 exposing a partial region of the buffer layer 103 and blocking the remaining regions of the buffer layer 103 is formed on the buffer layer 103. The mask pattern 105 may be formed by a Chemical Vapor Deposition (CVD) method inside or outside a Metal Organic Chemical Vapor Deposition (MOCVD) reactor so as to have a surface coverage of 50% for a surface area of the buffer layer 103. A thickness of the mask pattern 105 formed in this case is determined by aforementioned Equations 1 and 2 so as to optimize a reflective index of the light extraction structure. A material of the mask pattern 105 is the same as those described with reference to FIG. 1.

Referring to FIG. 6C, a semiconductor layer 107 covering the buffer layer 103 and the mask pattern 105 is formed. The semiconductor layer 107 may be grown from the buffer layer 103 exposed by the mask pattern 105. The semiconductor layer 107 may be grown by using a selective growth method or an Epitaxial Lateral OverGrowth (ELOG) method. In this case, a thickness of a partial region of the semiconductor layer 107 formed on the mask pattern 105 is compared to a thickness of the second layer B illustrated in FIG. 1, and is determined by aforementioned Equation 3 so as to optimize the reflectance of the DBR light extraction structure. A material of the semiconductor layer 107 is the same as those described with reference to FIG. 1.

Referring to FIGS. 6D and 6E, a DBR light extraction structure 113 including a plurality of pairs of mask patterns 105 and semiconductor layers 107 is formed by repeatedly performing the process of forming the mask pattern 105 described with reference to FIG. 6B and the process of forming the semiconductor layer 107 described with reference to FIG. 6C.

The number of stacked pairs 110_1 to 110_N of mask patterns 105 and semiconductor layers 107 forming the DBR light extraction structure 113 is determined by aforementioned Equation 4 so as to optimize the reflectance of the DBR light extraction structure 113.

Referring to FIG. 6F, an n-type semiconductor layer 115, an active layer 117, a p-type semiconductor layer 119, and a p-type contact layer 123 are grown on the DBR light extraction structure 113. The semiconductor layer 115, the active layer 117, the p-type semiconductor layer 119, and the p-type contact layer 123 may be grown by the MOCVD method or a Molecular Beam Epitaxy (MBE) method.

The DBR light extraction structure 113 formed according to the exemplary embodiment of the present invention may improve internal quantum efficiency of the active layer 117 by preventing dislocation generated by lattice mismatch between the substrate 101 and the buffer layer 103 from being progressed to the active layer 117. Further, the thicknesses and the number of staked pairs of mask patterns 105 and semiconductor layers 107 of the DBR light extraction structure 113 formed according to the exemplary embodiment of the present invention are controlled so as to optimize reflectance. Further, the DBR light extraction structure 113 is disposed at a lower side of the active layer 117. Accordingly, even though a Patterned Sapphire Substrate (PSS) is not included, the DBR light extraction structure 113 according to the exemplary embodiment of the present invention has high reflectance and reflects light emitted from the active layer 117 to the substrate 101 side, thereby improving light extraction efficiency.

FIG. 7 is a cross-sectional view illustrating a part of the light emitting diode according to the exemplary embodiment of the present invention.

Referring to FIG. 7, threading dislocation 111 is generated by the lattice mismatch between the substrate 101 and the buffer layer 103. The mask pattern 105 formed on the buffer layer 103 blocks the threading dislocation 111 from being transmitted to the semiconductor layer 107 formed on the mask pattern 105. Further, the semiconductor layer 107 at the upper side of the mask pattern 105 is grown in a direction of a lateral surface, so that even though the threading dislocation 111 is transmitted to the semiconductor layer 107 at the upper side of the mask pattern 105 through the opening region of the mask pattern 105, the threading dislocation 111 is progressed in the direction of the lateral surface, not the upper direction. Accordingly, the multilayer DBR light extraction structure, in which the mask patterns 105 and the semiconductor layers 107 are alternately stacked, has a lower dislocation density as being close to the upper side, and prevents the threading dislocation 111 from being transmitted to the light emitting structure formed at the upper side.

As described above, according to the present invention, the DBR is formed by alternately stacking the mask pattern 105 preventing the threading dislocation and the semiconductor layer 107 covering the mask pattern 105 in multi layers, and is used as the light extraction structure. Accordingly, the present invention may provide the high quality active layer having low dislocation density by preventing the threading dislocation from being progressed to the light emitting structure through the mask pattern, thereby improving internal quantum efficiency of the light emitting structure. Simultaneously, the present invention may reflect light emitted from the light emitting structure to head toward the substrate side to the outside (particularly, the upper side of the light emitting structure), thereby improving light extraction efficiency.

As described above, the embodiment has been disclosed in the drawings and the specification. The specific terms used herein are for purposes of illustration, and do not limit the scope of the present invention defined in the claims. Accordingly, those skilled in the art will appreciate that various modifications and another equivalent example may be made without departing from the scope and spirit of the present disclosure. Therefore, the sole technical protection scope of the present invention will be defined by the technical spirit of the accompanying claims.

What is claimed is:

1. A light emitting diode, comprising:
a buffer layer formed on a substrate;
a Distributed Bragg Reflector (DBR) formed in a multilayer structure, in which mask patterns including opening regions and semiconductor layers formed on the mask patterns while being filled in the opening regions of the mask patterns are alternately formed, and formed on the buffer layer; and
a light emitting structure formed on the DBR.

2. The light emitting diode of claim 1, wherein the mask pattern is formed of a dielectric material having a transmittance property.

3. The light emitting diode of claim 2, wherein the dielectric material includes SiO₂ or SiNₓ (x is a positive number).

4. The light emitting diode of claim 1, wherein the buffer layer and the semiconductor layer are formed of a nitride semiconductor.

5. The light emitting diode of claim 4, wherein the nitride semiconductor includes AlN or AlGaN.

6. The light emitting diode of claim 1, wherein a dislocation density of the semiconductor layer is decreased as being close to an upper layer in the multilayer structure of the DBR.

7. The light emitting diode of claim 1, wherein a thickness d₁ of the mask pattern meets Equation 1 below,
$${d}_{1} = \frac{λ}{4 \times {n}_{eff}} \qquad [ Equation 1 ]$$
in equation 1, λ indicates a wavelength of light emitted in the light emitting structure, and n_{eff} meets Equation 2 below,
n_{eff}=(1−α)n₂+αn₁ [Equation 2]
in Equation 2, α indicates surface coverage of the mask pattern, n₁ indicates a refractive index of the mask pattern, and n₂ indicates a refractive index of the semiconductor layer.

8. The light emitting diode of claim 1, wherein a thickness d₂ of the semiconductor layer meets Equation 3 below,
$${d}_{2} = \frac{λ}{4 \times {n}_{2}} \qquad [ Equation 3 ]$$
in equation 3, λ indicates a wavelength of light emitted in the light emitting structure, and n₂ meets a refractive index of the semiconductor layer.

9. The light emitting diode of claim 1, wherein the number N of stacked pairs of mask patterns and semiconductor layers meets Equation 4 below,
$$R = {[ \frac{{{n}_{0} ( {n}_{2} )}^{2 N} - {{n}_{s} ( {n}_{eff} )}^{2 N}}{{{n}_{0} ( {n}_{2} )}^{2 N} - {{n}_{s} ( {n}_{eff} )}^{2 N}} ]}^{2} \qquad [ Equation 4 ]$$
in Equation 4, R indicates reflectance of the DBR, n₀ indicates a refractive index of a layer which is in contact with the DBR among the layers forming the light emitting structure, n_{eff} indicates an effective refractive index of the layer in which the mask pattern is formed, n₂ indicates a refractive index of the semiconductor layer, and nₛ indicates a refractive index of the substrate.

10. The light emitting diode of claim 1, wherein the light emitting structure includes:
an n-type semiconductor layer formed on the DBR;
an active layer formed on the n-type semiconductor layer; and
a p-type semiconductor layer formed on the active layer.

11. A method of manufacturing a light emitting diode, comprising:
forming a buffer layer on a substrate;
forming a Distributed Bragg Reflector (DBR) having a multilayer structure by alternately stacking mask patterns and semiconductor layers on the buffer layer; and
forming a light emitting structure on the DBR.

12. The method of claim 11, wherein the forming of the mask pattern includes depositing the mask pattern so that the mask pattern has surface coverage of 50% by using a Chemical Vapor Deposition (CVD) method inside or outside a Metal Organic Chemical Vapor Deposition (MOCVD) reactor.

13. The method of claim 11, wherein the forming of the semiconductor layer is performed by using a selective growth method or an Epitaxial Lateral Overgrowth (ELOG) method.

14. The method of claim 11, wherein the forming of the light emitting structure includes:
forming an n-type semiconductor layer on the DBR;
forming an active layer on the n-type semiconductor layer; and
forming a p-type semiconductor layer on the active layer.
